(19) United States
(12) Patent Application Publication
(10) Pub. No.: US 2026/0035831 A1
(43) Pub. Date: Feb. 5, 2026

(54) METHODS, SYSTEMS, AND DEVICES FOR CONTROLLING CRYSTAL GROWTH DEVICES

(71) Applicant: MEISHAN BOYA ADVANCED MATERIALS CO., LTD., Meishan (CN)

(72) Inventors: Yu WANG, Meishan (CN); Pei LEI, Chengdu (CN)

(73) Assignee: MEISHAN BOYA ADVANCED MATERIALS CO., LTD., Meishan (CN)

(21) Appl. No.: 19/356,057

(22) Filed: Oct. 11, 2025

Related U.S. Application Data
(63) Continuation of application No. PCT/CN2023/087466, filed on Apr. 11, 2023.

(51) Int. Cl. C30B 23/00; C30B 29/36

(52) U.S. Cl. CPC C30B 23/002; C30B 29/36

(57) ABSTRACT

Disclosed herein are a method, a system, and a device for controlling a crystal growth device. The method includes: obtaining historical growth data of at least one crystal growth device, the historical growth data including historical growth control data and historical growth result data; and determining a control mode of a target crystal growth device based on the historical growth data and a target growth result, the control mode including at least one of a temperature control mode and a power control mode.

### CROSS-REFERENCE

This application is a continuation of International Application No. PCT/CN2023/087466, filed on Apr. 11, 2023, the entire content of which is incorporated herein by reference.

### TECHNICAL FIELD

The present disclosure relates to the field of semiconductor technology, and in particular, to a method, a system, and a device for controlling a crystal growth device.

### BACKGROUND

The growth of silicon carbide crystals is challenging, requiring stringent temperature control within a crystal growth device (such as a crystal growth furnace) during a crystal growth process. During the crystal growth process, the temperature inside the crystal growth device fluctuates with the growth process of the material, and failure to precisely control the temperature inside the crystal growth device may lead to quality issues (e.g., excessive convexity, stray crystals, etc.) in the grown silicon carbide crystals.

Therefore, it is desirable to provide a method, a system, and a device for controlling the crystal growth device, which monitors the crystal growth process during silicon carbide crystal growth and enables automated regulation based on the growth conditions of the crystal, thereby improving the quality of crystal growth.

### SUMMARY

One of the embodiments of the present disclosure provides a method for controlling a crystal growth device. The method may include obtaining historical growth data of at least one crystal growth device. The historical growth data may include historical growth control data and historical growth result data. The method may also include determining a control mode of a target crystal growth device based on the historical growth data and a target growth result. The control mode may include at least one of a temperature control mode and a power control mode.

One of the embodiments of the present disclosure provides a system for controlling a crystal growth device. The system may include an obtaining module for obtaining historical growth data of at least one crystal growth device. The historical growth data may include historical growth control data and historical growth result data. The system may also include a determination module for determining a control mode of a target crystal growth device based on the historical growth data and a target growth result. The control mode may include at least one of a temperature control mode and a power control mode.

One of the embodiments of the present disclosure provides a device for controlling a crystal growth device. The device may include a processor. The processor may be used to perform a method for controlling a crystal growth device as described in the above embodiment.

### BRIEF DESCRIPTION OF THE DRAWINGS

The present disclosure will be further illustrated by way of exemplary embodiments, which will be described in detail by means of the accompanying drawings. These embodiments are not limiting, and in these embodiments, the same numbering denotes the same structure, wherein:

FIG. 1 is an exemplary schematic diagram illustrating an application scenario of a system for controlling a crystal growth device according to some embodiments of the present disclosure;

FIG. 2 is an exemplary modular diagram illustrating a system for controlling a crystal growth device according to some embodiments of the present disclosure;

FIG. 3 is an exemplary block diagram illustrating an exemplary crystal growth device according to some embodiments of the present disclosure;

FIG. 4 is an exemplary flowchart illustrating a process for controlling a crystal growth device according to some embodiments of the present disclosure;

FIG. 5 is a schematic diagram illustrating a process for determining a control mode of a target crystal growth device according to some embodiments of the present disclosure;

FIG. 6 is an exemplary flowchart illustrating a process for determining a first control mode of a target crystal growth device according to some embodiments of the present disclosure;

FIG. 7 is an exemplary flowchart illustrating a process for determining a second control mode of a target crystal growth device according to some embodiments of the present disclosure;

FIG. 8 is a schematic diagram illustrating a process for determining a target growth power of a target crystal growth device according to some embodiments of the present disclosure;

FIG. 9 is an exemplary flowchart illustrating a process for determining a thermal insulation parameter of a target crystal growth device according to some embodiments of the present disclosure;

FIG. 10 is an exemplary flowchart illustrating a process for determining a quality parameter of a growth result according to some embodiments of the present disclosure;

FIG. 11 is an exemplary schematic diagram illustrating a process for determining a target control recipe of a target crystal growth device according to some embodiments of the present disclosure; and

FIG. 12 is an exemplary schematic diagram illustrating different growth stages of a target crystal growth device according to some embodiments of the present disclosure.

### DETAILED DESCRIPTION

To more clearly illustrate the technical solutions of the embodiments of the present disclosure, the accompanying drawings required to be used in the description of the embodiments are briefly described below. Obviously, the accompanying drawings in the following description are only some examples or embodiments of the present disclosure, and it is possible for a person of ordinary skill in the art to apply the present disclosure to other similar scenarios in accordance with these drawings without creative labor. Unless obviously obtained from the context or the context illustrates otherwise, the same numeral in the drawings refers to the same structure or operation.

It should be understood that, as used herein, the terms “system”, “device”, “unit,” and/or “module” as used herein is a method for distinguishing between different components, elements, parts, sections, or assemblies at different levels. However, the words may be replaced by other expressions if other words accomplish the same purpose.

As shown in the specification and the claims, unless the context clearly suggests an exception, the words “a”, “an”, “one”, and/or “the” do not refer specifically to the singular, but may also include the plural. In general, the terms “including” and “comprising” only suggest the inclusion of explicitly identified steps and elements that do not constitute an exclusive list, and the method or device may also include other steps or elements.

Flowcharts are used in the present disclosure to illustrate operations performed by a system according to embodiments of the present disclosure. It should be appreciated that the preceding or following operations are not necessarily performed in an exact sequence. Instead, steps may be processed in reverse order or simultaneously. Also, it is possible to add other operations to these processes, or to remove a step or steps from these processes.

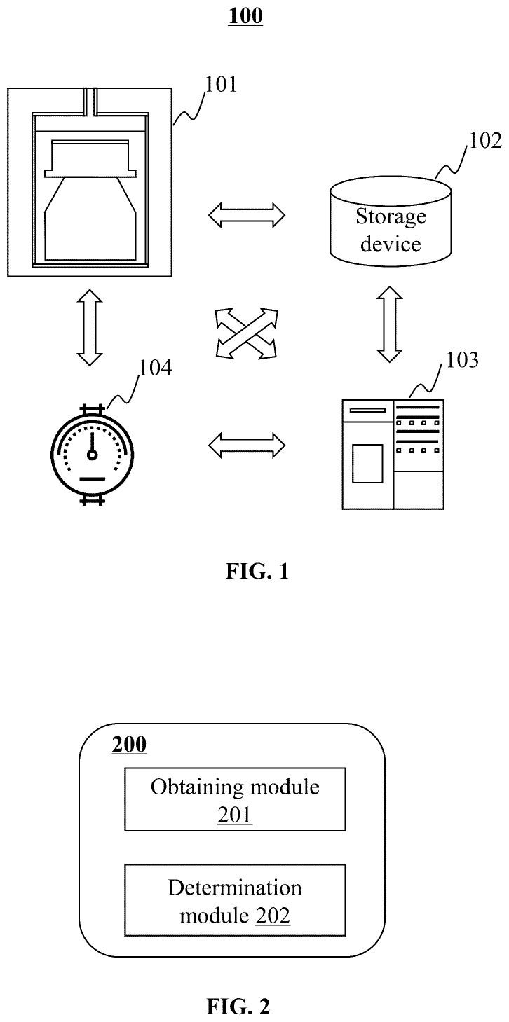

FIG. 1 is an exemplary schematic diagram illustrating an application scenario of a system for controlling a crystal growth device according to some embodiments of the present disclosure. In some embodiments, the application scenario 100 of the system for controlling the crystal growth device, as illustrated in FIG. 1, may include a crystal growth device 101, a storage device 102, a processing device 103, and a monitoring device 104.

The crystal growth device 101 refers to a device used for crystal growth. The crystal growth device 101 may include, but is not limited to, a physical vapor transport (PVT) crystal growth device, a liquid phase epitaxy (LPE) crystal growth device, a Czochralski (CZ) crystal growth device, or the like.

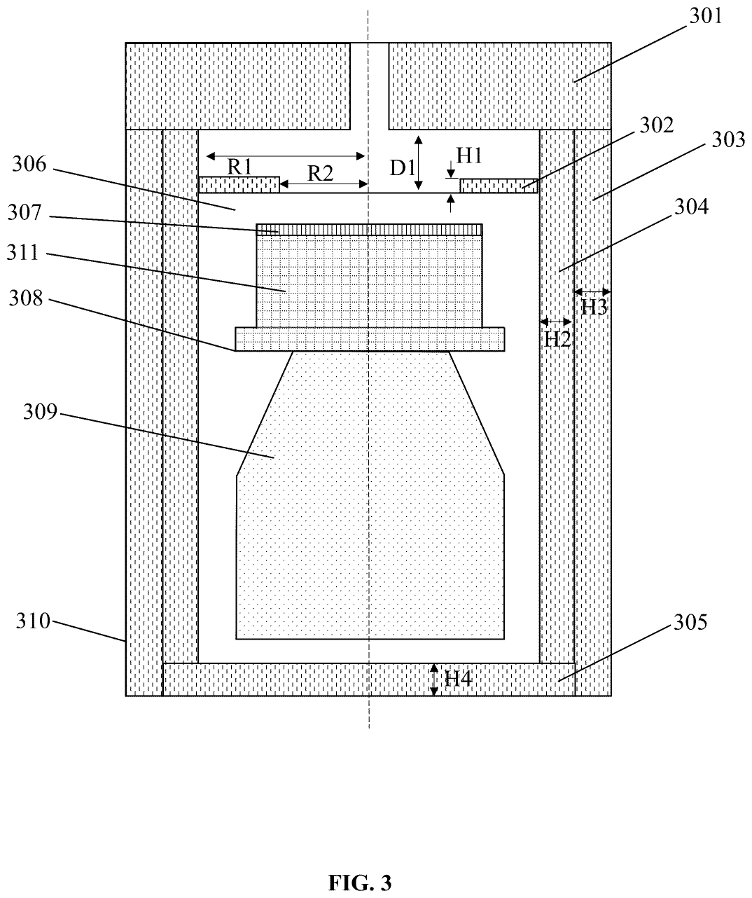

Merely by way of example, the crystal growth device 101 may be a silicon carbide crystal growth furnace, and as shown in FIG. 3, the crystal growth device 101 may include a furnace body 310, a crucible 306, a thermal insulation material, and a heating coil (not shown in the figure). The furnace body 310 may accommodate other structures of the crystal growth device 101. The heating coil may be used to control temperature inside the furnace body 310. The crucible 306 is provided inside the furnace body 310. In some embodiments, the crucible 306 may include a raw material chamber 309 and a growth chamber 311 separated by a gasket 308, the raw material chamber 309 may be used to hold silicon carbide powder, and the growth chamber 311 may be used to grow silicon carbide crystals. In some embodiments, the growth chamber 311 may include a crystal growth position 307 (e.g., a position for setting a seed crystal). The thermal insulation material may be used to maintain or regulate the temperature inside the furnace body 310. The temperature and a temperature field distribution inside the furnace body 310 may be changed by setting one or more thermal insulation parameters of the thermal insulation material, which affects the growth of the silicon carbide crystals inside the crystal growth device 101. In some embodiments, the thermal insulation material may include a top insulation layer 301, a crucible top insulation layer 302, an outer cylinder insulation layer 303, an inner cylinder insulation layer 304, and a bottom insulation layer 305. In some embodiments, the one or more thermal insulation parameters of the thermal insulation material may include a distance D1 between a top of the crucible 306 and the top insulation layer 301, an outer diameter R1 of the crucible top insulation layer 302, an inner diameter R2 of the crucible top insulation layer 302, a thickness H1 of the crucible top insulation layer 302, a thickness H3 of the outer cylinder insulation layer 303, a thickness H2 of the inner cylinder insulation layer 304, a thickness H4 of the bottom insulation layer 305, or the like, or a combination thereof.

The crystal growth device 101 may interact with the storage device 102 for data. For example, the crystal growth device 101 may send relevant growth data (e.g., growth control data, growth result data, a device parameter, etc.) to a storage device (e.g., the storage device 102) for storage in real time during a crystal growth process. The crystal growth device 101 may interact with the processing device 103 for data. For example, the crystal growth device 101 may set or adjust a control mode and a growth control parameter, etc., according to an instruction from the processing device 103.

The storage device 102 may store data, instructions, and/or any other information. In some embodiments, the storage device 102 may store data and/or the instructions used by the processing device 103 to be executed or used to accomplish the exemplary methods described herein.

In some embodiments, the storage device 102 may store data information of the crystal growth device 101, the processing device 103, and the monitoring device 104. For example, the storage device 102 may store historical growth data of the crystal growth device 101 during a historical crystal growth process. As another example, when the historical growth data and a target growth result of the crystal growth device 101 are sent to the processing device 103 for further processing, the processing device 103 may store processed data (e.g., the control mode and the growth control parameter) to the storage device 102.

In some embodiments, the storage device 102 may include a mass memory, a removable memory, a volatile read-write memory, a read-only memory (ROM), etc., or any combination thereof. In some embodiments, the storage device 102 may be implemented on a cloud platform. In some embodiments, the storage device 102 may be part of the processing device 103.

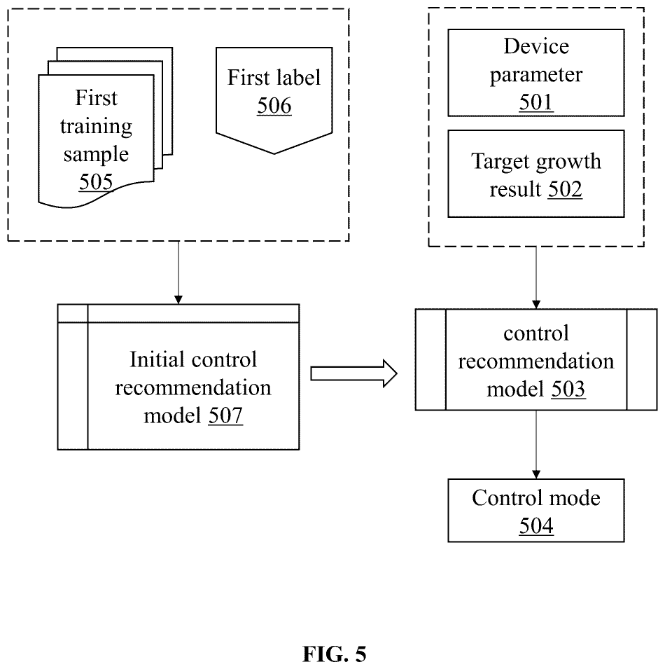

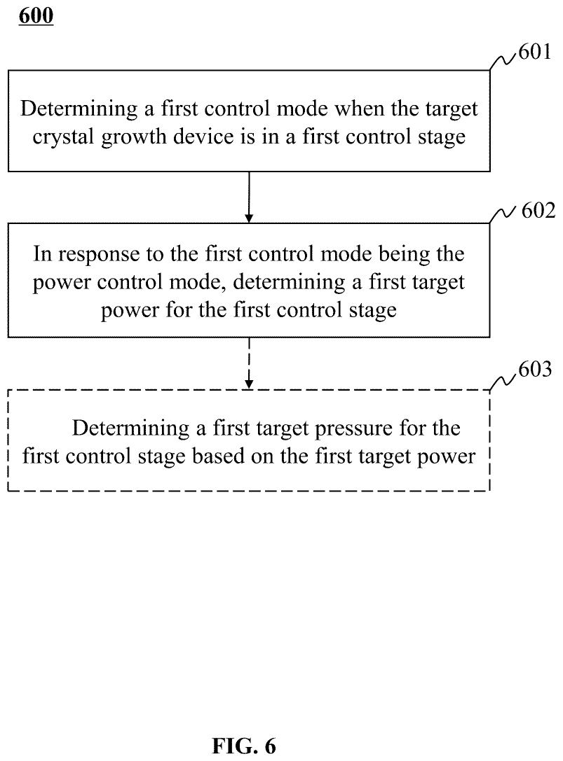

The processing device 103 may process data and/or information obtained from the crystal growth device 101, the storage device 102, and/or the monitoring device 104. The processing device 103 may execute program instructions based on such data, information, and/or processing results to perform one or more of the functions described in this application. For example, the processing device 103 may obtain the historical growth data of at least one crystal growth device, and determine the control mode of the target crystal growth device based on the historical growth data and a target growth result. More details regarding determining the control mode may be found in FIGS. 5, 6, 7, and the related descriptions. As another example, the processing device 103 may determine the growth control parameter of the target crystal growth device based on the control mode and the target growth result of the target crystal growth device. In response to a first control mode of the target crystal growth device being a power control mode, the processing device 103 may determine a first target power and a first target pressure for the target crystal growth device in the first control stage. In response to a second control mode of the target crystal growth device being a temperature control mode, the processing device 103 may determine a target temperature and a target growth power for the target crystal growth device in the second control stage. More details regarding determining the growth control parameter may be found in FIGS. 6, 7, 8, and the related descriptions.

In some embodiments, the processing device 103 may be local or remote. In some embodiments, the processing device 103 may include one or more sub-processing devices (e.g., a single-core processing device or a multi-core multi-chip processing device). Merely by way of example, the processing device 103 may include a central processing unit (CPU), an application-specific integrated circuit (ASIC), an application-specific instruction processor (ASIP), a graphics processor (GPU), a physical processor (PPU), a digital signal processor (DSP), a field-programmable gate array (FPGA), a programmable logic circuit (PLD), a controller, a microcontroller unit, a reduced instruction set computer (RISC), a microprocessor, etc. or any combination of the above.

The monitoring device 104 may be used to obtain data related to the crystal growth process. For example, the monitoring device 104 may be used to obtain pressure information, temperature information, gas flow information, etc., in the crystal growth device 101 during the crystal growth process. In some embodiments, the monitoring device 104 may include, but is not limited to, a temperature monitoring device (e.g., a temperature sensor, a thermometer, etc.), a pressure monitoring device (e.g., a pressure sensor, etc.), a gas flow monitoring device (e.g., a flow meter, etc.), etc. The monitoring device 104 may interact with the storage device 102 for data, and send obtained monitoring data to the storage device 102 for storage. The monitoring device 104 may interact with the processing device 103 for data, and send the obtained monitoring data to the processing device 103 for processing.

In the application scenario 100 of the system for controlling the crystal growth device, data interaction between various components may be implemented through a network or data connection. The network may be a wired network or a wireless network (e.g., WIFI, Bluetooth, etc.).

It should be noted that the foregoing description is provided for illustrative purposes only and is not intended to limit the scope of the present disclosure. For a person of ordinary skill in the art, a wide variety of variations and modifications may be made under the guidance of the contents of the present disclosure. Features, structures, methods, and other characteristics of the exemplary embodiments described herein may be combined in various ways to obtain additional and/or alternative exemplary embodiments. For example, the crystal growth device 101, the processing device 103, and the monitoring device 104 may share a common storage device 102, or may have separate storage devices. However, the variations and modifications do not depart from the scope of the present disclosure.

FIG. 2 is an exemplary modular diagram illustrating a system for controlling a crystal growth device according to some embodiments of the present disclosure. In some embodiments, the system 200 for controlling the crystal growth device may include an obtaining module 201 and a determination module 202. In some embodiments, the system 200 for controlling the crystal growth device may be implemented by the processing device 103.

The obtaining module 201 may be configured to obtain historical growth data of at least one crystal growth device.

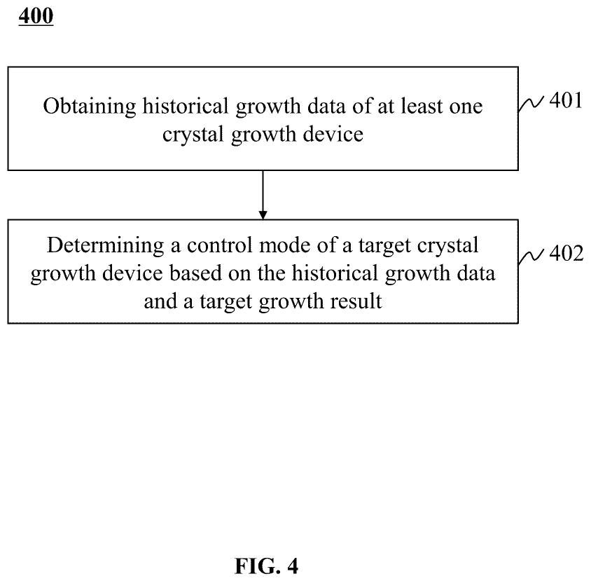

The determination module 202 may be configured to determine a control mode of a target crystal growth device based on the historical growth data and a target growth result. In some embodiments, the determination module 202 may obtain one or more device parameters of the target crystal growth device; and determine the control mode of the target crystal growth device based on the one or more device parameters of the target crystal growth device, the historical growth data, and the target growth result. More details regarding determining the control mode may be found in FIG. 4 and the related descriptions.

In some embodiments, the determination module 202 may determine the control mode of the target crystal growth device by using a control recommendation model to process the one or more device parameters and the target growth result. The control recommendation model is a machine learning model. More details regarding the control recommendation model may be found in FIG. 5 and the related descriptions.

In some embodiments, the determination module 202 may also be configured to determine one or more growth control parameters of the target crystal growth device based on the control mode and the target growth result of the target crystal growth device. More details regarding determining the growth control parameters may be found in FIG. 4 and the related descriptions.

In some embodiments, the determination module 202 may be configured to determine a first control mode when the target crystal growth device is in a first control stage. The first control stage is a feedstock preheating stage. More details regarding determining the first control mode may be found in FIG. 6 and the related descriptions.

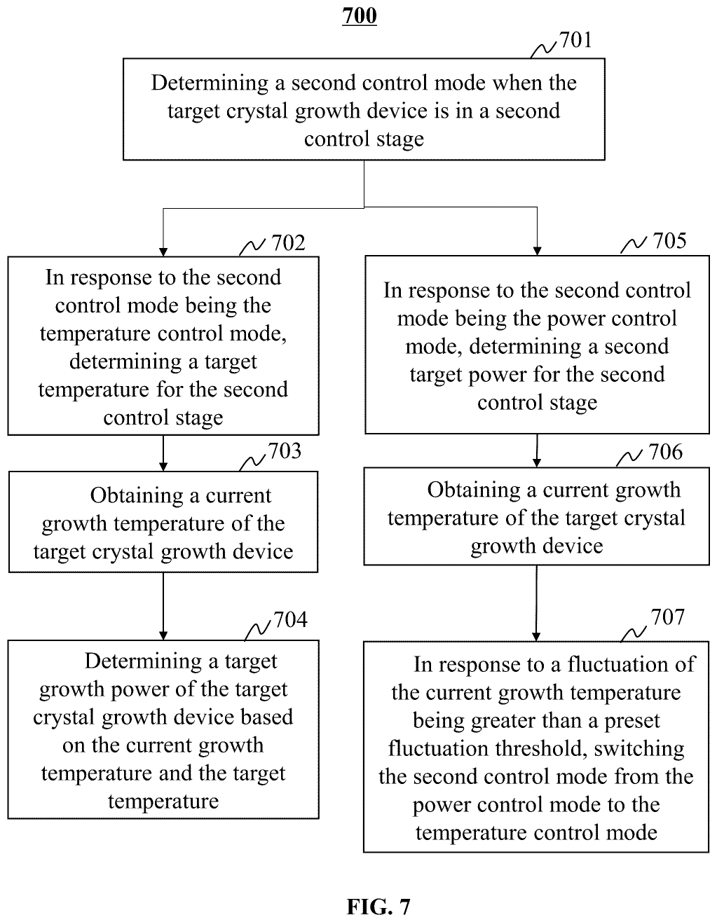

In some embodiments, the determination module 202 may be configured to determine a second control mode when the target crystal growth device is in a second control stage. The second control stage is a crystal growth stage. More details regarding the second control mode may be found in FIG. 7 and the related descriptions.

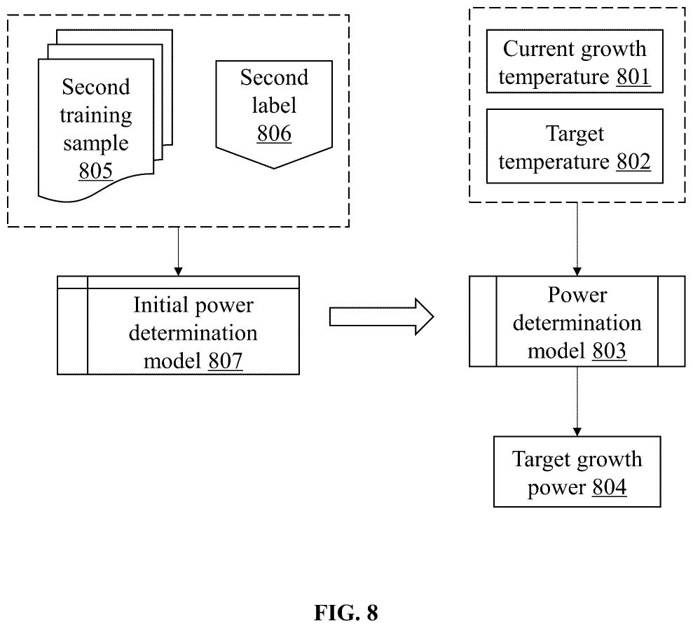

In some embodiments, in response to the second control mode being a temperature control mode, the determination module 202 may be configured to determine a target temperature for the second control stage; obtain a current growth temperature of the target crystal growth device; and determine a target growth power of the target crystal growth device based on the current growth temperature and the target temperature. More details regarding determining the target growth power may be found in FIG. 8 and the related descriptions.

In some embodiments, in response to the second control mode being a power control mode, the determination module 202 may be configured to determine a second target power for the second control stage. The second target power is used to control the target crystal growth device during the second control stage.

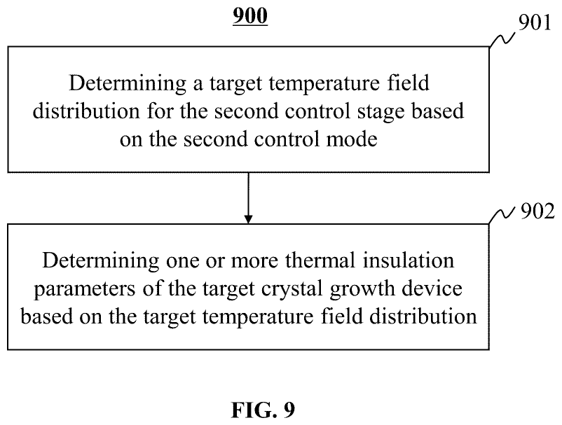

In some embodiments, the determination module 202 may be configured to determine a target temperature field distribution for the second control stage based on the second control mode; and determine one or more thermal insulation parameters of the target crystal growth device based on the target temperature field distribution. More details regarding determining the one or more thermal insulation parameters may be found in FIG. 9 and the related descriptions.

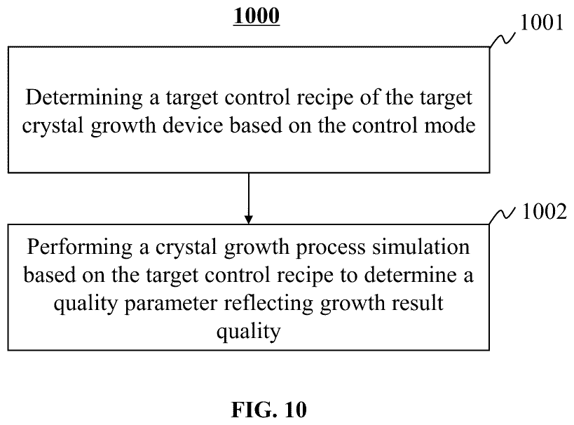

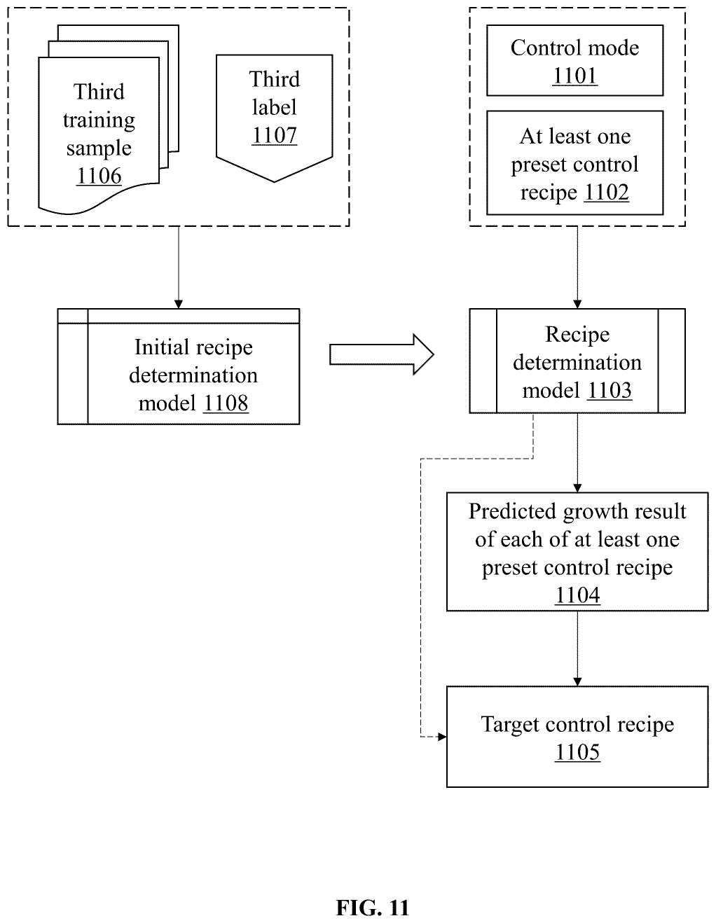

In some embodiments, the determination module 202 may be configured to determine a target control recipe of the target crystal growth device based on the control mode. More details regarding determining the target control recipe may be found in FIG. 10, FIG. 11, and related descriptions thereof.

In some embodiments, the determination module 202 may be configured to perform a crystal growth process simulation based on the target control recipe to determine a quality parameter reflecting growth result quality. More details regarding determining the quality parameter reflecting the quality of growth result quality may be found in FIG. 11 and the related descriptions.

It should be noted that the above description of the system 200 for controlling the crystal growth device and its modules is provided only for descriptive convenience, and does not limit the present disclosure to the scope of the embodiments cited. It is to be understood that for a person skilled in the art, after understanding the principle of the system, it may be possible to arbitrarily combine the modules or form a subsystem to connect with other modules without departing from the principle. In some embodiments, the obtaining module 201 and the determination module 202 may be different modules in a single system, or a single module may implement the functions of two or more of the modules described above. For example, individual modules may share a common storage module, and the individual modules may each have a respective storage module. Morphisms such as these are within the scope of protection of the present disclosure.

FIG. 4 is an exemplary flowchart illustrating a process for controlling a crystal growth device according to some embodiments of the present disclosure.

In some embodiments, the process for controlling the crystal growth device may be performed by a processor or the system 200 for controlling the crystal growth device. For example, process 400 may be stored in a storage device (e.g., the storage device 102) in a form of a program or an instruction, and the process 400 may be implemented when the processor or the system 200 for controlling the crystal growth device executes the program or the instruction. Operations of the process 400 presented below are illustrative. In some embodiments, the process may be accomplished utilizing one or more additional operations that are not described and/or one or more operations that are not discussed. Additionally, an order of the operations of the process 400 illustrated in FIG. 4 and described below is not limiting.

In 401, historical growth data of at least one crystal growth device may be obtained.

The historical growth data refers to data related to a historical crystal growth process (i.e., a historical crystal growth procedure) of each of the at least one crystal growth device.

In some embodiments, the historical growth data may include historical growth control data and historical growth result data.

The historical growth control data refers to growth control data of a crystal growth device during the historical crystal growth process. In some embodiments, the growth control data may include a control mode, a growth control parameter, one or more thermal insulation parameters, etc., of a crystal growth device at each of different control stages during the crystal growth process. In some embodiments, the historical growth control data may include a historical control mode, one or more historical growth control parameters, one or more historical thermal insulation parameters, etc., of each of one or more crystal growth devices at different control stages during the historical crystal growth process.

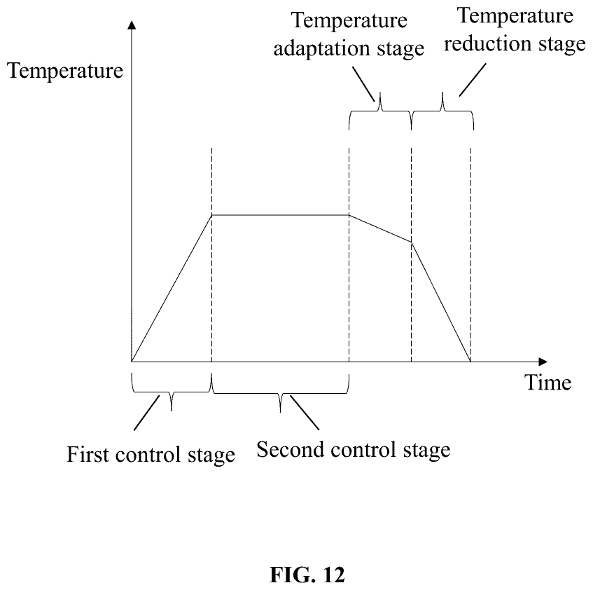

The control stages refer to stages in the crystal growth process divided by the crystal growth device based on temperature control conditions during the crystal growth process. In some embodiments, as shown in FIG. 12, the control stages in the crystal growth process may include a first control stage, a second control stage, a temperature adaptation stage, and a temperature reduction stage. The first control stage is a feedstock preheating stage. In the feedstock preheating stage, the temperature of the crystal growth device is continuously increased to a certain temperature (also referred to as a growth temperature), allowing a raw material within the crystal growth device to reach the growth temperature gradually. The first control stage ends with the second control stage. The second control stage is a crystal growth stage. During the crystal growth stage, the temperature of the crystal growth device is kept constant at or near the growth temperature (temperature fluctuation of no more than ±0.1° C.). The second control stage ends with the temperature adaptation stage. During the temperature adaptation stage, the temperature of the crystal growth device is gradually lowered from the growth temperature to a temperature close to the surface of the crystal. The temperature adaptation stage ends with the temperature reduction stage. During the temperature reduction stage, the temperature of the crystal growth device is gradually reduced to room temperature (e.g., 25° C.±5° C.).

The control mode refers to an operating mode used to control the crystal growth device. More details regarding the control mode may be found in operation 402 and the related descriptions. A growth control parameter refers to a relevant parameter used to control crystal growth. Further description of the growth control parameter may be found in the related descriptions below. A thermal insulation parameter refers to a relevant parameter used to thermalize the crystal growth device. Further description of the thermal insulation parameter may be found in FIG. 9 and the related descriptions.

The historical growth result data refers to data relating to crystals (e.g., silicon carbide single crystals) produced by each of the at least one crystal growth device during the historical crystal growth process.

In some embodiments, the growth result data may include a thickness, size, a convexity range, a concavity range, a crystal quality condition, a slice thickness, a count of slices, etc., of a crystal. The crystal quality condition may include the presence of defects, a defect type (e.g., including defects such as phase transition, dislocation, microtubule, inclusion, etc.), and the severity of the defects. The severity of the defects may be labeled and classified by a human based on a priori knowledge or experience.

In some embodiments, the historical growth data may also include one or more historical device parameters of each of the at least one crystal growth device. A historical device parameter refers to a device parameter of a crystal growth device used during the historical crystal growth process. The device parameters corresponding to different crystal growth devices may be different. In some embodiments, the device parameters of the crystal growth device may be set as desired, and the device parameters of the same crystal growth device may be set to be the same, or may be set to be different for different batches of the crystal growth process. In some embodiments, the device parameters may include, but are not limited to, an ultimate vacuum degree, a pressure control range, a pressure control precision at different pressure levels, a maximum heating temperature, a temperature control precision, a power control range, a power control precision, etc., of the crystal growth device.

In some embodiments, the historical growth data of the at least one crystal growth device may be read from the storage device. The storage device may be the storage device 102 integrated into the control system of the crystal growth device, or an external storage device that is not a part of the control system of the crystal growth device, e.g., a hard disk, a compact disc (CD), etc. In some embodiments, the historical growth data of the at least one crystal growth device may be read through an interface. The interface includes, but is not limited to, a program interface, a data interface, a transmission interface, or the like. In some embodiments, the control system of the crystal growth device may automatically retrieve the historical growth data of the at least one crystal growth device from the interface. In some embodiments, the control system of the crystal growth device may be invoked by another external device or system, and upon invocation, the historical growth data of the at least one crystal growth device is passed to the control system of the crystal growth device. In some embodiments, the historical growth data of the at least one crystal growth device may be obtained in any manner known to those skilled in the art, and the present disclosure is not limited thereto.

In 402, the control mode of a target crystal growth device may be determined based on the historical growth data and a target growth result.

The target growth result refers to desired growth result data of the crystal growth device. More details regarding the growth result data may be found in the previous related descriptions. The target growth result may be obtained by user input. For example, the target growth result may be uploaded by the user from a user terminal.

The target crystal growth device refers to a crystal growth device that performs the current production.

The control mode refers to an operating mode used to control the target crystal growth device. Different control modes allow the target crystal growth device to control the temperature inside the crystal growth device (e.g., a growth chamber) in different ways.

In some embodiments, the control mode may include a temperature control mode and a power control mode.

In the temperature control mode, the processor may automatically adjust the power of the target crystal growth device to make the temperature of each of at least one temperature measurement point remain constant at a corresponding preset temperature (or the temperature fluctuates no more than ±0.1° C.). The at least one temperature measurement point may be located inside at least one of a crucible or a furnace body of the target crystal growth device. The preset temperatures corresponding to different temperature measurement points may be different. The position and a count of the at least one temperature measurement point, and the preset temperatures corresponding to the different temperature measurement points may be system default, empirical set, human preset, etc., or any combination thereof, and may be set according to the actual needs. The present disclosure does not impose any limitations.

In the power control mode, the processor may directly set the power of the target crystal growth device to make the target crystal growth device run according to a set power. In some embodiments, the set power may be an operating power of a heating coil in the target crystal growth device, and the heating coil may heat the target crystal growth device according to the set power. In some embodiments, the set power may be a fixed value. In some embodiments, the set power may also be a power value that varies over time.

The processor may determine the control mode of the target crystal growth device based on the historical growth data and the target growth result in a plurality of ways. For example, the processor may construct a target feature vector based on the historical growth data and the target growth result, match the target feature vector with one of the plurality of reference feature vectors in a vector database based on the target feature vector to determine, from the plurality of reference feature vectors, an associated feature vector that meets a preset condition; and based on a reference control mode of the target crystal growth device corresponding to the determined associated feature vector, determine the final control mode of the target crystal growth device.

The vector database refers to a vector database for storing, indexing, and querying vectors. The vector database enables fast similarity queries and other vector management for large numbers of vectors. In some embodiments, the vector database may include a plurality of reference feature vectors and the reference control modes of the target crystal growth device corresponding to the plurality of reference feature vectors.

In some embodiments, the processor may filter the historical growth data of a plurality of crystal growth devices to obtain the historical growth data that satisfies the corresponding historical target growth result, thereby constructing a reference feature vector. For example, the processor may obtain the plurality of reference feature vectors by performing feature extraction on the portion of the historical growth data and the historical target growth results. A manner of feature extraction may include: principal component analysis, machine learning, or the like. The reference control mode of the target crystal growth device corresponding to the reference feature vector may be obtained based on the historical growth data. In some embodiments, the processor may construct the vector database based on the plurality of reference feature vectors and the corresponding reference control modes of the target crystal growth device.

The preset condition refers to a judgment condition for determining the associated feature vectors. In some embodiments, the preset condition may include a vector distance satisfying a distance threshold, the vector distance being minimized, or the like.

In some embodiments, the processor may obtain the one or more device parameters of the target crystal growth device, and determine the control mode of the target crystal growth device based on the device parameters, the historical growth data, and the target growth result of the target crystal growth device. More details regarding the device parameter may be found in operation 401 and the related descriptions.

The one or more device parameters of the target crystal growth device may be obtained in a plurality of ways. For example, the one or more device parameters of the target crystal growth device may be obtained by user input. As another example, the one or more device parameter of the target crystal growth device may be read from the storage device. The storage device may be the storage device 102 integrated in the control system of the crystal growth device, or an external storage device that is not a part of the control system of the crystal growth device, for example, a hard disk, a CD, or the like. In some embodiments, the one or more device parameters of the target crystal growth device may be read through the interface. The interface includes, but is not limited to, a program interface, a data interface, a transmission interface, or the like. In some embodiments, the control system of the crystal growth device may automatically extract the one or more device parameters of the target crystal growth device from the interface. In some embodiments, the one or more device parameters of the target crystal growth device may be obtained in any way known to those skilled in the art, and the present disclosure does not limit this.

In some embodiments, the processor may determine the control mode of the target crystal growth device by a first preset reference table based on the one or more device parameters, the historical growth data, and the target growth result of the target crystal growth device. In some embodiments, the first preset reference table includes a plurality of different reference device parameters, a plurality of different reference growth results, and a plurality of corresponding relationships between the reference growth results, the reference device parameters, and the reference control modes. A reference growth result may be determined based on the historical growth result data in the historical growth data, and the reference device parameters corresponding to the reference growth result may be determined based on the one or more historical device parameters in the historical growth data. In some embodiments, the processor may construct the plurality of different reference device parameters, the plurality of different reference growth results, and the plurality of corresponding relationships between the reference growth results, the reference device parameters, and the reference control modes, based on prior knowledge or historical data, to obtain the first preset reference table. In some embodiments, the processor may search the first preset reference table based on the device parameters, the historical growth data, and the target growth result of the target crystal growth device to determine the reference device parameters that are similar to the device parameters, further determine a reference growth result that most closely matches the target growth result, and determine a reference control mode corresponding to the reference growth result as the control mode of the target crystal growth device.

In some embodiments, the processor may determine the control mode of the target crystal growth device by using a control recommendation model to process the one or more device parameters and the target growth result of the target crystal growth device. The control recommendation model is a machine learning model. More details regarding determining the control mode based on the control recommendation model may be found in FIG. 5 and the related descriptions.

In some embodiments, the target crystal growth device may have the same or different control modes at different control stages. The control mode corresponding to the target crystal growth device in the first control stage is also referred to as a first control mode, and the control mode corresponding to the second control mode is also referred to as a second control mode. Correspondingly, the processor may determine the first control mode when the target crystal growth device is in the first control stage, and the second control mode when the target crystal growth device is in the second control mode. More details regarding determining the first control mode and the second control mode may be found in FIG. 6, FIG. 7, and the respective descriptions.

In some embodiments of the present disclosure, by analyzing the historical growth data and the historical target growth result of the plurality of crystal growth devices, patterns in the historical crystal growth processes are summarized, which allows for automated adjustments of the parameters of the current crystal growth process based on the historical data, effectively reducing errors caused by manual adjustments. As a result, the actual growth result of the crystal growth device is better aligned with the target growth result, thereby ensuring the accuracy of automated control and improving the quality of crystal growth. At the same time, the control mode is determined based on the one or more device parameters of the crystal growth device, taking into full account the impact of the differences between different crystal growth devices on automated adjustments, thereby improving the precision of automated control.

In other embodiments, the control mode of the target crystal growth device may also be determined by user input, and the processor may access the control mode input by the user. In some embodiments, the user may input the control mode for each control stage (e.g., the first control stage, the second control stage, etc.) of the target crystal growth device, and the processor may obtain the control mode for the each control stage input by the user. In some embodiments, the control mode of the target crystal growth device may also be a preset default mode, and the processor may obtain the control mode for the each control stage from the target crystal growth device.

In some embodiments, after determining or obtaining the control mode of the target crystal growth device, the processor may determine the growth control parameter of the target crystal growth device based on the control mode and the target growth result of the target crystal growth device.

The growth control parameter refers to a relevant parameter used to control crystal growth. In some embodiments, the growth control parameter may include a temperature, a pressure, a power, a gas flow rate of the target crystal growth device, etc.

In some embodiments, the processor may determine the growth control parameter of the target crystal growth device based on the control mode and the target growth result of the target crystal growth device through a second preset reference table. In some embodiments, the second preset reference table includes corresponding relationships between a plurality of different reference control modes, a plurality of different reference growth results, and reference growth control parameters. In some embodiments, the processor may construct the corresponding relationships between the plurality of different reference control modes, the plurality of different reference growth results, and the reference growth control parameters based on priori knowledge or historical data to obtain the second preset reference table. In some embodiments, the processor may search the second preset reference table based on the control mode and the target growth result of the target crystal growth device, determine a reference control mode and a reference growth result that most closely match the control mode and the target growth result, and determine a reference growth control parameter corresponding to the reference control mode and the reference growth result as the growth control parameter of the target crystal growth device.

In some embodiments, the processor may determine the growth control parameter of the target crystal growth device by using the control recommendation model to process the device parameter and the target growth result of the target crystal growth device. More details regarding determining the growth control parameter based on the control recommendation model may be found in FIG. 5 and the related descriptions.

In some embodiments, the target crystal growth device may undergo a plurality of control stages during the crystal growth process, the control modes for different control stages may be different, and thus the growth control parameters for different control stages may be different. In some embodiments, the processor may first determine the control mode corresponding to a certain control stage and then determine the growth control parameter for the control stage.

In some embodiments, in response to the first control mode being the power control mode when the target crystal growth device is in the first control stage, the processor may determine a first target power of the target crystal growth device in the first control stage. More details regarding the first target power may be found in FIG. 6 and the related descriptions.

In some embodiments, in response to the second control mode being the temperature control mode when the target crystal growth device is in the second control mode, the processor may determine a target temperature of the target crystal growth device in the second control stage; and determine a target growth power of the target crystal growth device based on a current growth temperature and the target temperature of the target crystal growth device. More details regarding determining the target temperature of the target crystal growth device in the second control stage may be found in FIG. 7 and the related descriptions. More details regarding determining the target growth power of the target crystal growth device in the second control stage may be found in FIG. 8 and the related descriptions.

In some embodiments, in response to the second control mode being the power control mode when the target crystal growth device is in the second control stage, the processor may determine a second target power of the target crystal growth device in the second control stage. More details regarding determining the second target power of the target crystal growth device in the second control stage may be found in FIG. 7 and the related descriptions.

In some embodiments, the processor may also determine at least one of a second target pressure or a target gas flow for the second control stage based on the second control mode. More details regarding determining the second target pressure and the target gas flow may be found in FIG. 7 and the related descriptions.

FIG. 5 is a schematic diagram illustrating a process for determining a control mode of a target crystal growth device according to some embodiments of the present disclosure.

In some embodiments, as shown in FIG. 5, a processor may determine a control mode 504 of a target crystal growth device by using a control recommendation model 503 to process one or more device parameters 501 and a target growth result 502 of the target crystal growth device.

The control recommendation model 503 refers to a machine learning model for determining the control mode of the target crystal growth device. For example, the control recommendation model 503 may include one of a Neural Networks (NN) model, a Back Propagation Neural Network (BPNN), a Convolutional Neural Networks (CNN) model, etc., or any combination thereof.

In some embodiments, the control recommendation model 503 includes more than eight hundred multiplication operations in a single execution. In some embodiments, the control recommendation model 503 is at least partially executed by a GPU.

In some embodiments, an input of the control recommendation model 503 may include the one or more device parameters and the target growth result 502 of the target crystal growth device, and an output may include the control mode 504 of the target crystal growth device. More details regarding the device parameter, the target growth result, and the control mode may be found in FIG. 4 and the related descriptions.

In some embodiments, the output of the control recommendation model 503 may also include one or more growth control parameters of the target crystal growth device. More details regarding the growth control parameter may be found in FIG. 4 and the related descriptions.

In some embodiments, the control recommendation model 503 may be obtained by obtaining a plurality of first training samples 505 and first labels 506 corresponding to the plurality of first training samples 505, and based on the plurality of first training samples 505 and the first labels 506, and performing training to obtain the control recommendation model 503.

Exemplarily, the processor may input each of the plurality of first training samples 505 with the first labels 506 into an initial control recommendation model 507, construct a loss function through one of the first labels 506 corresponding to the each of the plurality of first training samples 505 and the output of the initial control recommendation model 507, and iteratively update parameters of the initial control recommendation model 507 through gradient descent or other manners based on the loss function. When a preset condition is satisfied, the training of the initial control recommendation model 507 is completed and the trained control recommendation model 503 is obtained. The preset condition may be that the loss function converges, a count of iterations reaches a threshold, or the like.

In some embodiments, each of the training samples (i.e., the plurality of first training samples 505) of the control recommendation model 503 include historical growth data. The historical growth data may be data whose historical growth result data is similar or comparable to a corresponding historical target growth result.

In some embodiments, each of the first training samples 505 includes one or more historical device parameters and a historical target growth result of a first sample crystal growth device. In some embodiments, first sample crystal growth devices may include a plurality of crystal growth devices. In some embodiments, the first sample crystal growth devices may include the target crystal growth device.

In some embodiments, one of the first labels 506 corresponding to one of the first training samples 505 may include at least one of a historical control mode or one or more historical growth control parameters of the first sample crystal growth device.

In some embodiments, one of the first labels 506 corresponding to one of the first training samples 505 may include historical control modes of the first sample crystal growth device at each historical control stage. For example, one of the first labels 506 corresponding to one of the first training samples 505 may be a historical first control mode of the first sample crystal growth device at a historical first control stage and a historical second control mode of the first sample crystal growth device at a historical second control stage.

In some embodiments, the processor may filter the historical growth data of the plurality of crystal growth devices to obtain the historical growth result data of each of at least a portion of the plurality of crystal growth devices that is similar to or close to the corresponding historical target growth result, thereby determining the first training samples 505 and the first labels 506. For example, the processor may identify the one or more historical device parameter in the historical growth data and the historical target growth result as a first training sample 505, and identify the historical control mode in the historical growth data as a first label 506. As another example, the processor may identify the historical growth control parameter in the historical growth data as a first label 506.

In some embodiments, the control recommendation model 503 may include an input layer, M hidden layers, and an output layer. The count of neurons in the input layer is equal to a count of input variables, and the count of neurons in the output layer is equal to a count of outputs associated with each input.

In some embodiments, M may be equal to two. In some embodiments, M may be an integer greater than or equal to two. In some embodiments, the count of neurons in the hidden layer may be determined based on a count of first training samples, the count of neurons in the input layer, and the count of neurons in the output layer. An exemplary determination formula is as follows:

$$N = \frac{H}{α \times ( P + Q )}$$

where N denotes the count of neurons in the hidden layer, H denotes the count of first training samples, P denotes the count of neurons in the input layer, Q denotes the count of neurons in the output layer, and a denotes a conditioning constant between 2 and 10.

In some embodiments, the control recommendation model 503 includes an activation function. In some embodiments, the activation function may include, but is not limited to, a Rectified Linear Unit (ReLU). In some embodiments, the activation function may include a first activation function and a second activation function, and the first activation function may be of the same type as the second activation function. In some embodiments, a Dropout layer may be included between the first activation function and the second activation function, and an initial parameter of the Dropout layer may be set to 0.2. The initial parameter may be gradually reduced according to the training effect of the control recommendation model.

In some embodiments of the present disclosure, the control mode and the growth control parameter of the target crystal growth device can be determined based on a large number of extensive features through the control recommendation model, which allows the predicted control mode and the growth control parameter of the crystal growth device to achieve higher accuracy, enabling high-precision automated regulation of the crystal growth process in actual production.

FIG. 6 is an exemplary flowchart illustrating a process for determining a first control mode of a target crystal growth device according to some embodiments of the present disclosure. In some embodiments, the process of determining the first control mode may be performed by a processor or the system 200 for controlling a crystal growth device. For example, the process 600 may be stored in a storage device (e.g., the storage device 102) in a form of a program or an instruction, and the process 600 may be implemented when the processor or the system 200 for controlling the crystal growth device executes the program or the instruction. An operational diagram of the process 600 presented below is illustrative. In some embodiments, the process may be accomplished utilizing one or more additional operations that are not described and/or one or more not discussed operations. Additionally, an order of the operations of the process 600 illustrated in FIG. 6 and described below is not limiting.

In 601, the first control mode when the target crystal growth device is in a first control stage may be determined.

The first control stage may be a feedstock preheating stage. More details regarding the first control stage may be found in FIG. 12 and the related descriptions.

The first control mode refers to a control mode used for controlling the target crystal growth device when the target crystal growth device is in the first control stage.

In some embodiments, the processor may determine the first control mode when the target crystal growth device is in the first control stage in a plurality of ways. For example, the processor may determine the first control mode when the target crystal growth device is in the first control stage by performing data fitting, statistical analysis, and other processing on historical growth data. As another example, the processor may determine the first control mode when the target crystal growth device is in the first control stage by using a control recommendation model to process one or more device parameters and a target growth result of the target crystal growth device. More details regarding the control recommendation model may be found in FIG. 5 and the related descriptions. As yet another example, the processor may determine the first control mode when the target crystal growth device is in the first control stage based on a first preset rule. The exemplary first preset rule may be: determining the first control mode based on the accuracy of temperature measurements at one or more temperature measurement points. If the accuracy of temperature measurements in the first control stage is lower than a preset value, i.e., it is not possible to accurately obtain an actual temperature value of the temperature measurement point in the first control stage, then when the target crystal growth device is in the first control stage, the first control mode is a power control mode. In some embodiments, the accuracy of the temperature measurements at the temperature measurement points when the target crystal growth device is in the first control stage may be determined based on the historical growth data of the target crystal growth device.

In other embodiments, the processor may determine the first control mode of the target crystal growth device by obtaining user input. In other embodiments, the target crystal growth device is preset with the control mode for the first control stage, and the processor may obtain information from the target crystal growth device to determine the first control mode of the target crystal growth device.

In 602, in response to the first control mode being a power control mode, a first target power for the first control stage may be determined.

In some embodiments, the first target power may be a fixed power set for the target crystal growth device in the power control mode, and the target crystal growth device may operate at the fixed power directly in the first control stage. In some embodiments, the target crystal growth device may gradually increase the operating power during actual operation, in which case the first target power may be a power when the target crystal growth device stops adjusting the operating power, i.e., the target crystal growth device may remain operating at the first target power when the operating power reaches the first target power.

In some embodiments, the first target power may be used to control the target crystal growth device during the first control stage. For example, in the first control stage, the processor may control the target crystal growth device to adjust the operating power according to a certain power adjustment amplitude until the operating power of the target crystal growth device increases to the first target power, stop the adjustment, and maintain the operating power of the target crystal growth device at the first target power.

In some embodiments, the processor may determine the first target power for the first control stage in a plurality of ways.

In some embodiments, the processor may determine the first target power for the first control stage by the control recommendation model. For example, the processor may determine the first target power when the target crystal growth device is in the first control stage by using the control recommendation model to process the one or more device parameters and the target growth result of the target crystal growth device. Correspondingly, a first label used to train the control recommendation model, i.e., a historical growth control parameter of a first sample crystal growth device, may include a historical first target power when the first sample crystal growth device is in a historical first control stage. More details regarding the control recommendation model may be found in FIG. 5 and the related descriptions.

When the temperature of the target crystal growth device reaches a certain temperature value (the temperature value may be subsequently referred to as a critical temperature), power input is stopped, and the temperature of the target crystal growth device may continue to rise to a certain extent and eventually stabilize at a demand temperature value of the first control stage.

In some embodiments, the processor may determine the critical temperature of the target crystal growth device in the first control stage in a plurality of ways. In the power control mode, the processor may control the target crystal growth device to stop power input when the temperature of the target crystal growth device reaches the critical temperature.

In some embodiments, the processor may determine the critical temperature for the first control stage by the control recommendation model. For example, the processor may determine the critical temperature when the target crystal growth device is in the first control stage by using the control recommendation model to process the one or more device parameters and the target growth result of the target crystal growth device. Correspondingly, the first label used to train the control recommendation model, i.e., the historical growth control parameter of the first sample crystal growth device, may include a historical critical temperature when the first sample crystal growth device is in the historical first control stage. More details regarding the control recommendation model may be found in FIG. 5 and the related description.

In some embodiments, the processor may determine the critical temperature for the first control stage through a critical temperature determination model. For example, the processor may determine the critical temperature when the target crystal growth device is in the first control stage by using the critical temperature determination model to process the one or more device parameters and the target growth result of the target crystal growth device.

The critical temperature determination model may be a machine learning model, e.g., a CNN model, a Deep Neural Network (DNN) model, etc.

In some embodiments, the critical temperature determination model includes more than eight hundred multiplication operations in a single execution. In some embodiments, the critical temperature determination model is at least partially executed by a GPU.

In some embodiments, the critical temperature determination model may be obtained based on fourth training samples with fourth labels. In some embodiments, each of the fourth training samples may include one or more historical device parameters and a historical growth result of a fourth sample crystal growth device. A fourth label of a fourth training sample may include the historical critical temperature of the fourth sample crystal growth device during the historical first control stage. The critical temperature determination model may be trained in a manner referable to the training of the control recommendation model, and more may be found in FIG. 5 and the related descriptions.

In some embodiments, after the temperature of the target crystal growth device in the first control stage is stabilized within a certain temperature value range in the power control mode, the temperature in the target crystal growth device may not be able to reach a constant temperature state directly, and then the temperature in the target crystal growth device may be adjusted to the constant temperature state by adjusting a pressure of the target crystal growth device. In the constant temperature state, temperatures at various positions inside the target crystal growth device are identical or approximately the same (for example, temperature fluctuation does not exceed ±1° C.). More details regarding how to determine the constant temperature state, please refer to FIG. 7 and the related descriptions.

Determining how to make adjustments to the pressure of the target crystal growth device is described below in operation 603. It should be noted that the operation 603 is not a required operation to be performed, and that the operation 603 may be not performed after the operation 601 and the operation 602.

In 603, a first target pressure for the first control stage may be determined based on the first target power.

The first target pressure refers to a value of the pressure that adjusts the temperature of the target crystal growth device to the constant temperature state.

In some embodiments, the processor may determine the first target pressure for the first control stage in a plurality of ways.

In some embodiments, the processor may determine the first target pressure for the first control stage by the control recommendation model. For example, the processor may determine the first target pressure for the target crystal growth device in the first control stage by using the control recommendation model to process the one or more device parameters and the target growth result of the target crystal growth device. Correspondingly, the first label used to train the control recommendation model, i.e., the historical growth control parameter of the first sample crystal growth device, may include a historical first target pressure of the first sample crystal growth device in the historical first control stage. More details regarding the control recommendation model may be found in FIG. 5 and the related descriptions.

In some embodiments, after determining the first target pressure, the processor may adjust the pressure of the target crystal growth device based on the first target pressure by a preset pressure adjustment manner. An exemplary pressure adjustment manner may include: adjusting a pressure in a furnace to change a pressure difference between the furnace and a crucible. For example, the processor may adjust the pressure in the furnace by controlling the amount of air coming into the furnace (positive pressure) or out (negative pressure).

In other embodiments, the processor may determine the control mode when the target crystal growth device is in the first control stage as a temperature control mode based on the historical growth data. When the first control stage is in the temperature control mode, the processor may determine a relationship (e.g., a temperature-time curve) of the temperature over time for the first control stage based on the historical growth data, and then control an input power of the target crystal growth device to make the temperature within the target crystal growth device varies in strict accordance with the relationship of the temperature over time.

FIG. 7 is an exemplary flowchart illustrating a process for determining a second control mode of a target crystal growth device according to some embodiments of the present disclosure. In some embodiments, the process for determining the second control mode may be performed by a processor or the system 200 for controlling a crystal growth device. For example, the process 700 may be stored in a storage device (e.g., the storage device 102) in a form of a program or an instruction, and the process 700 may be implemented when the processor or the system 200 for controlling the crystal growth device executes the program or the instruction. An operational diagram of the process 700 presented below is illustrative. In some embodiments, the process may be accomplished utilizing one or more additional operations that are not described and/or one or more not discussed operations. Also, an order of operations of the process 700 illustrated in FIG. 7 and described below is not limiting.

In 701, the second control mode when the target crystal growth device is in a second control stage may be determined.

The second control stage may be a crystal growth stage. More details regarding the second control stage may be found in FIG. 12 and the related descriptions.

The second control mode refers to a control mode used for controlling the target crystal growth device when the target crystal growth device is in the second control mode.

In some embodiments, the processor may determine the second control mode when the target crystal growth device is in the second control mode in a plurality of ways. For example, the processor may determine the second control mode when the target crystal growth device is in the second control mode by using a control recommendation model to process the one or more device parameters and a target growth result of the target crystal growth device. More details regarding the control recommendation model may be found in FIG. 5 and the related descriptions.

In other embodiments, the processor may also determine the second control mode for the target crystal growth device by obtaining user input. In other embodiments, the target crystal growth device is preset with the control mode for the second control stage, and the processor may obtain information from the target crystal growth device to determine the second control mode of the target crystal growth device.

It should be noted that when the second control modes are different control modes, different growth control parameters may be determined. The following may explain the case where the second control mode is a temperature control mode through operations 702-704, and the case where the second control mode is a power control mode through operations 705-707. An order between the operations 702 704 and the operations 705-707 is not limited.

In 702, in response to the second control mode being the temperature control mode, a target temperature for the second control stage may be determined.

The target temperature refers to a preset temperature to be reached by the target crystal growth device in the temperature control mode. In some embodiments, the target temperature may be a temperature that the target crystal growth device needs to maintain during the crystal growth stage. In some embodiments, the target temperature may be the same as or approximately the same as the temperature of a constant temperature state achieved during the first control stage.

In some embodiments, the processor may determine the target temperature for the second control stage in a plurality of ways.

In some embodiments, the processor may determine the target temperature for the second control stage by the control recommendation model. For example, the processor may determine the target temperature when the target crystal growth device is in the second control stage by using the control recommendation model to process the one or more device parameters and the target growth result of the target crystal growth device. Correspondingly, the first label used to train the control recommendation model, i.e., a historical growth control parameter of a first sample crystal growth device, may include a historical target temperature when the first sample crystal growth device is in a historical second control stage. More details regarding the control recommendation model may be found in FIG. 5 and the related descriptions.

In 703, a current growth temperature of the target crystal growth device may be obtained.

The current growth temperature refers to a temperature of the target crystal growth device at a current moment. In some embodiments, the current moment may be a moment when the target crystal growth device has just entered the second control stage. In some embodiments, the current moment may be a moment when the target crystal growth device is in the second control stage.

In some embodiments, the processor may obtain the current growth temperature of the target crystal growth device in real time via a monitoring device (e.g., a temperature monitoring device). For example, the processor may monitor in real time a temperature at a crystal growth position in the target crystal growth device through the temperature monitoring device to obtain the current growth temperature.

In some embodiments, the processor may obtain the current growth temperature based on at least three temperature measurement points. For example, the processor may obtain the current growth temperature of the target crystal growth device by processing, such as weighting, the temperature values detected by the at least three temperature measurement points.

In some embodiments, the at least three temperature measurement points have different axial positions. An axial direction refers to a direction perpendicular to a bottom plane of the crystal growth device. The different axial positions of the at least three temperature measurement points refer to that the at least three temperature measurement points are not on the same horizontal plane. For example, one temperature measurement point may be at a bottom position of a crucible (e.g., a bottom center), one temperature measurement point may be at a top position of the crucible (e.g., a top center), and the rest of the temperature measurement points may be between the two temperature measurement points.

In 704, a target growth power of the target crystal growth device may be determined based on the current growth temperature and the target temperature.

The target growth power of the target crystal growth device refers to a power condition of the target crystal growth device in the second control stage. When the second control mode of the second control stage is the temperature control mode, the target growth power may fluctuate to stabilize the temperature of the target crystal growth device. In some embodiments, the target growth power may be used to control the target crystal growth device during the second control stage. In some embodiments, the target growth power may be determined in real time based on the current growth temperature and the target temperature. In some embodiments, the target growth power may be represented by a power curve with time on a horizontal axis and a growth power on a vertical axis, which may be generated in real time based on the current growth temperature and the target temperature.

In some embodiments, the processor may determine the target growth power of the target crystal growth device based on the current growth temperature and the target temperature in a plurality of ways.

In some embodiments, the processor may determine the target growth power of the target crystal growth device by using a power determination model to process the current growth temperature and the target temperature. More details regarding the target growth power based on the power determination model may be found in FIG. 8 and the related descriptions.

In 705, in response to the second control mode being the power control mode, a second target power for the second control stage may be determined.

The second target power refers to a power of the target crystal growth device that is preset in the second control stage under the power control mode. In some embodiments, the second target power may be a constant power value. In some embodiments, the second target power may be a set power value that varies over time, a correspondence between the power value and the time may be constant after setting.

In some embodiments, the second target power may be used to control the target crystal growth device during the second control stage. For example, the processor may control the power of the target crystal growth device to remain at the second target power during the second control stage.

In some embodiments, the processor may determine the second target power for the second control stage in a plurality of ways.

In some embodiments, the processor may determine the second target power for the second control stage by the control recommendation model. For example, the processor may determine the second target power when the target crystal growth device is in the second control stage by using the control recommendation model to process the one or more device parameters and the target growth result of the target crystal growth device. Correspondingly, the first label used to train the control recommendation model, i.e., the historical growth control parameter of the first sample crystal growth device, may include a historical second target power of the first sample crystal growth device in the historical second control stage. More details regarding the control recommendation model may be found in FIG. 5 and the related descriptions.

In the power control mode, since the target crystal growth device operates according to the set power, it may not be able to handle unexpected situations that arise during a crystal growth process, potentially leading to poorer crystal growth results. At this point, the processor may monitor a real-time temperature situation during the crystal growth process to take corresponding measures based on the real-time temperature situation. The following may be further explained by operation 706 and operation 707. It should be noted that the operation 706 and the operation 707 are not mandatory steps to be performed, and the operation 706 and the operation 707 may be discontinued after the operation 705.

In 706, the current growth temperature of the target crystal growth device may be obtained.

More details regarding the current growth temperature and the way it is obtained may be found in the operation 703 and the related descriptions.

In 707, in response to a fluctuation of the current growth temperature being greater than a preset fluctuation threshold, the second control mode may be switched from the power control mode to the temperature control mode.

The fluctuation of the current growth temperature refers to a temperature difference between the current growth temperature at the current moment and a growth temperature at a previous moment. The previous moment may be a moment prior to the current moment. In some embodiments, an interval of moments for obtaining the current temperature may be preset, for example, may be set to 1 second, 2 seconds, 5 seconds, or the like.

In some embodiments, in response to the fluctuation of the current growth temperature being greater than the preset fluctuation threshold, the processor may issue at least one of a reminder instruction or an alarm instruction to control at least one of an associated reminder device or an alarm device to carry out at least one of reminder or alarm.

In some embodiments, in response to the fluctuation of the current growth temperature being greater than the preset fluctuation threshold, the processor may switch the second control mode from the power control mode to the temperature control mode. When the second control mode is switched to the temperature control mode, the processor may automatically adjust then operating power of the target crystal growth device to make the temperature of at least one temperature measurement point or the temperature of each of the at least three temperature measurement points remains constant at the growth temperature at the previous moment (or the temperature fluctuation is not more than ±0.1° C.).

In some embodiments, when the second control mode is switched from the power control mode to the temperature control mode, the processor may control the associated reminder device to alert.

In some embodiments, an unexpected condition during the growth process of a crystal may result in a drastic change in the growth temperature thereof, greatly affecting the crystal growth results. Correspondingly, the processor may also determine whether the fluctuation of the current growth temperature is greater than a preset alarm threshold, and in response to the fluctuation of the current growth temperature being greater than the preset alarm threshold, the processor may control the target crystal growth device to stop operating.

It should be noted that the preset fluctuation threshold and the preset alarm threshold may be threshold conditions related to temperature fluctuations. The preset fluctuation threshold and the preset alarm threshold are incremented sequentially. In some embodiments, the preset fluctuation threshold and the preset alarm threshold may be system default, empirical set, human preset, etc., or any combination thereof, which may be set according to the actual demand, and the present disclosure does not impose any limitations thereon. For example, the preset fluctuation threshold may be ±0.1° C., and the preset alarm threshold may be ±2° C.

In some embodiments of the present disclosure, the control process of the crystal growth device is divided into a plurality of control stages according to the control of the temperature during the crystal growth process. The crystal growth process can be controlled in segments by determining the control mode and the growth control parameter of each control stage. The accuracy of automated control can be improved, thereby suggesting the quality of crystal growth. Additionally, by monitoring the crystal growth process in real-time during practical applications and determining whether each parameter is changing according to normal patterns, it is possible to promptly and accurately identify any abnormalities in the crystal growth process, which allows for timely reminders, alarms, and/or adjustments based on the actual situation.

In some embodiments, to ensure the quality of the crystal growth, in the second control stage, the processor may realize the automated regulation of the crystal growth process by controlling some other parameters. For example, the processor may realize the automated regulation of the crystal growth process by controlling a temperature field distribution of the target crystal growth device in the second control stage. More details regarding controlling the temperature field distribution may be found in FIG. 9 and the related descriptions. As another example, the processor may realize the automated regulation of the crystal growth process by controlling the pressure and the gas flow of the target crystal growth device in the second control stage, as described later.

In some embodiments, the processor may determine at least one of a second target pressure or a target gas flow for the second control stage based on the second control mode.

In some embodiments, the processor may determine at least one of the second target pressure or the target gas flow for the second control stage based on the second control mode in a plurality of ways.

In some embodiments, the processor may determine at least one of a second target pressure or a target gas flow for the second control stage under different control modes using the control recommendation model, and thereby determining, based on the second control mode, at least one of the corresponding second target pressure or the target gas flow. For example, the processor may determine at least one of the target pressure or the target gas flow under different control modes when the target crystal growth device is in the second control stage by using the control recommendation model to process the one or more device parameters and the target growth result of the target crystal growth device.

In some embodiments, an output of the control recommendation model may be represented as a vector. For example, the output of the control recommendation model may be a vector [(m, a1, b1)(n, a2, b2)], m denotes that the second control mode is the power control mode, a1 denotes the second target pressure when the second control mode is the power control mode, b1 denotes the target gas flow when the second control mode is the power control mode, n denotes that the second control mode is the temperature control mode, a2 denotes the second target pressure when the second control mode is the temperature control mode, and b2 denotes the target gas flow when the second control mode is the temperature control mode.

In some embodiments, the first label used to train the control recommendation model, i.e., the historical growth control parameter of the first sample crystal growth device, may include a historical second target pressure and a historical target gas flow of the first sample crystal growth device under each of different control modes during the historical second control stage. More details regarding the control recommendation model may be found in FIG. 5 and the related descriptions.

In some embodiments of the present disclosure, the control recommendation model can accurately determine the second target pressure and the target gas flow of the target crystal growth device in the second control stage, which in turn can realize the automated control of the crystal growth process with high precision in the actual production process, and improve the quality of crystal growth.

FIG. 8 is a schematic diagram illustrating a process for determining a target growth power of a target crystal growth device according to some embodiments of the present disclosure.

In some embodiments, when a second control mode is a temperature control mode, the processor may determine the target growth power 804 of the target crystal growth device by using a power determination model 803 to process a current growth temperature 801 and a target temperature 802 of the target crystal growth device.

The power determination model 803 refers to a machine learning model for determining the target growth power of the target crystal growth device. For example, the power determination model 803 may include one of a DNN model, a CNN model, etc., or any combination thereof.

In some embodiments, the power determination model 803 includes more than eight hundred multiplication operations in a single execution. In some embodiments, the power determination model 803 is at least partially executed by a GPU.

In some embodiments, an input of the power determination model 803 may include the current growth temperature 801 and the target temperature 802 of the target crystal growth device, and an output may include the target growth power 804 of the target crystal growth device. More details regarding the current growth temperature, the target temperature, and the target growth power may be found in FIG. 7 and the related descriptions.

In some embodiments, the power determination model 803 may be obtained by obtaining a plurality of second training samples 805 and second labels 806 corresponding to the plurality of second training samples 805, and based on the plurality of second training samples 805 and the second labels 806, performing training to obtain the power determination model 803.

Exemplarily, the processor may input each of the plurality of second training samples 805 with the second labels 806 into an initial power determination model 807, construct a loss function through one of the second labels 806 corresponding to the each of the plurality of second training samples 805 and an output of the initial power determination model 807, and iteratively update parameters of the initial power determination model 807 through gradient descent or other manners based on the loss function. When a preset condition is satisfied, the training of the initial power determination model 807 is completed and the trained power determination model 803 is obtained. The preset condition may be that the loss function converges, a count of iterations reaches a threshold, or the like.

In some embodiments, each of the second training samples 805 include a historical current growth temperature and a historical target temperature of a second sample crystal growth device when the second control mode is the temperature control mode. In some embodiments, second sample crystal growth devices may include a plurality of crystal growth devices. In some embodiments, the second sample crystal growth devices may include the target crystal growth device. In some embodiments, the second sample crystal growth devices may be the same as the first sample crystal growth devices.

In some embodiments, each of the second labels 806 may include a historical target growth power of the second sample crystal growth device.

In some embodiments, the processor may filter historical growth data of the plurality of crystal growth devices to obtain the historical growth result data of each of at least a portion of the plurality of crystal growth devices that is similar or close to corresponding historical target growth result, thereby determining the second training samples 805 and the second labels 806. For example, the processor may identify the historical current growth temperature and historical target temperature in the historical growth data when the second control mode is the temperature control mode as a second training sample 805, and identify the historical target growth power in the historical growth data when the second control mode is the temperature control mode as a second label 806.

In some embodiments of the present disclosure, the target growth power of the target crystal growth device is determined through the power determination model, enabling the system or device for controlling the crystal growth device to automatically and accurately determine the growth control parameter of the crystal growth device, thereby achieving regulation of the crystal growth process.

FIG. 9 is an exemplary flowchart illustrating a process for determining a thermal insulation parameter of a target crystal growth device according to some embodiments of the present disclosure. In some embodiments, the process for determining the thermal insulation parameter may be performed by a processor or the system 200 for controlling a crystal growth device. For example, the process 900 may be stored in a storage device (e.g., the storage device 102) in a form of a program or an instruction, and the process 900 may be implemented when the processor or the system 200 for controlling the crystal growth device executes the program or the instruction. An operational diagram of the process 900 presented below is illustrative. In some embodiments, the process may be accomplished utilizing one or more additional operations that are not described and/or one or more operations that are not discussed. Also, an order of operations of the process 900 illustrated in FIG. 9 and described below is not limiting.

In 901, a target temperature field distribution for a second control stage may be determined based on a second control mode.

The temperature field distribution may affect an airflow direction within the crystal growth device, and the airflow direction may affect the movement of gas-phase components inside the crystal growth device, thereby impacting convexity, concavity, or quality of the grown crystals.

The target temperature field distribution refers to a temperature field distribution necessary to ensure that the crystals get a target growth result.

In some embodiments, the processor may determine the target temperature field distribution for the second control stage based on the second control mode in a plurality of ways.

In some embodiments, the processor may determine the target temperature field distribution for the second control stage under different control modes using a control recommendation model, and thereby determining the corresponding target temperature field distribution based on the second control mode. For example, the processor may determine the target temperature field distribution under different control modes when the target crystal growth device is in the second control stage by using the control recommendation model to process one or more device parameters and the target growth result of the target crystal growth device.

In some embodiments, an output of the control recommendation model may be represented as a vector. For example, the output of the control recommendation model may be a vector [(m, c1)(n, c2)], m denotes that the second control mode is a power control mode, c1 denotes one target temperature field distribution, n denotes that the second control mode is a temperature control mode, and c2 denotes another target temperature field distribution.

In some embodiments, a first label used to train the control recommendation model, i.e., a historical growth control parameter of a first sample crystal growth device, may include a historical target temperature field distribution of the first sample crystal growth device under each of different control modes during a historical second control stage. More details regarding the control recommendation model may be found in FIG. 5 and the related descriptions.

In 902, one or more thermal insulation parameters of the target crystal growth device may be determined based on the target temperature field distribution.

The one or more thermal insulation parameters may be used to adjust the temperature field distribution of the target crystal growth device.

In some embodiments, the one or more thermal insulation parameters may include at least one of an outer diameter parameter of a first insulation layer, an inner diameter parameter of the first insulation layer, a first thickness parameter of the first insulation layer, and a second thickness parameter of a second insulation layer.

Referring to FIG. 3, the first insulation layer may be the crucible top insulation layer 301 of a crystal growth device. The second insulation layer may include the outer cylinder insulation layer 303, the inner cylinder insulation layer 304, and the bottom insulation layer 305 of the crystal growth device, etc., or a combination thereof. The first thickness parameter refers to a thickness of the first insulation layer, and the second thickness parameter refers to a thickness of each of the second insulation layers.

In some embodiments, the processor may determine the thermal insulation parameter of the target crystal growth device based on the target temperature field distribution and a third preset reference table. In some embodiments, the third preset reference table includes a corresponding relationship between a plurality of different reference temperature field distributions and reference thermal insulation parameters. In some embodiments, the corresponding relationship between the plurality of different reference temperature field distributions and the reference thermal insulation parameters may be constructed based on priori knowledge or historical data to obtain the third preset reference table. In some embodiments, the processor may search the third preset reference table based on the target temperature field distribution, determine the reference temperature field distribution that most closely matches the target temperature field distribution, and determine the reference thermal insulation parameter corresponding to the reference temperature field distribution as the thermal insulation parameter of the target crystal growth device.

In some embodiments, the processor may determine one or more recommendation schemes of thermal insulation layers based on the one or more thermal insulation parameters.

The recommendation schemes of thermal insulation layers refer to the configuration pertaining to a thickness and a model types of the first insulation layer or the second insulation layer.

In some embodiments, the processor may determine the one or more recommendation schemes of thermal insulation layers based on the thermal insulation parameter in a plurality of ways. For example, the processor may determine a model type of a replacement insulation layer for replacing the current first insulation layer based on the outer diameter parameter, the inner diameter parameter, and first thickness parameter of the first insulation layer in the one or more thermal insulation parameter. As another example, the processor may determine a model type of a candidate insulation layer of the second insulation layer based on the second thickness parameter of the second insulation layer in the thermal insulation parameter.

In some embodiments of the present disclosure, by determining the temperature field distribution of the crystals during the crystal growth stage and the target temperature field distribution in real time, the temperature field distribution of the target crystal growth device can be adjusted by determining the thermal insulation parameter and the recommending the configuration scheme of the insulation layer, which reduces the impact of the airflow direction on the quality of the crystals and improves the quality of crystal growth.

FIG. 10 is an exemplary flowchart illustrating a process for determining a quality parameter of a growth result according to some embodiments of the present disclosure. In some embodiments, the process for determining the quality parameter may be performed by a processor or the system 200 for controlling a crystal growth device. For example, the process 1000 may be stored in a storage device (e.g., the storage device 102) in a form of a program or an instruction, and the process 1000 may be implemented when the processor or the system 200 for controlling the crystal growth device executes the program or the instruction. An operational diagram of the process 1000 presented below is illustrative. In some embodiments, the process may be accomplished utilizing one or more additional operations that are not described and/or one or more not discussed operations. Also, an order of operations of the process 1000 illustrated in FIG. 10 and described below is not limiting.

In 1001, a target control recipe of a target crystal growth device may be determined based on a control mode.

A control recipe refers to a scheme for controlling the crystal growth device to adjust control parameters at an appropriate time during a crystal growth process. The target control recipe refers to a finalized control recipe for controlling the target crystal growth device. In some embodiments, the target control recipe may include one or more control modes and one or more growth control parameters. For example, the target control recipe may be: a first control mode is a power control mode, a first target power is j, a first target pressure is q; a second control mode is a temperature control mode, a target growth power is p, a second target power is g, a target temperature field distribution is k, a thermal insulation parameter is h, a second target pressure is f, and a target gas flow is r.

In some embodiments, the processor may determine the target control recipe of the target crystal growth device based on the control mode in a plurality of ways.

In some embodiments, the processor may, after determining the growth control parameters of the target crystal growth device, formulate the growth control parameters into a corresponding control recipe. For example, the processor may first determine the growth control parameters for a first control stage and generate a control recipe applicable to the first control stage based on the growth control parameters for the first control stage. As another example, the processor may first determine the growth control parameters for a second control stage and generate a control recipe applicable to the second control stage based on the growth control parameters for the second control stage. As yet another example, the processor may first determine the growth control parameters for the first control stage and the second control stage, and generate a control recipe based on the growth control parameters for the first control stage and the second control stage.

In some embodiments, the processor may determine the target control recipe from a plurality of preset control recipes based on the control mode. In some embodiments, a preset control recipe may be a preset control recipe for controlling the target crystal growth device. In some embodiments, a preset control recipe may be a pre-stored, human-set control recipe. In some embodiments, a preset control recipe may be determined by the processor.

In some embodiments, the processor may determine the preset control recipe in a plurality of ways. For example, the processor may use a historical control recipe from historical data as the preset control recipe. As another example, the processor may select one of a plurality of preset parameter values as one of a recipe scheme for the preset control recipe. Further example, the processor may directly generate a preset control recipe.

In some embodiments, the processor may determine a predicted growth result of each of at least one preset control recipe by using a recipe determination model to process the control mode and the each of the at least one preset control recipe and determine the target control recipe based on a plurality of predicted growth results. More details regarding determining the target control recipe based on the recipe determination model may be found in FIG. 11 and the related descriptions.

In 1002, a crystal growth process simulation may be performed based on the target control recipe to determine a quality parameter reflecting growth result quality.

The quality parameter refers to one or more evaluation values used to evaluate the good growth result or bad growth result quality. In some embodiments, the quality parameter may include evaluation values for a plurality of evaluation terms. For example, the quality parameter includes an evaluation value corresponding to a crystal thickness, an evaluation value corresponding to a crystal size, an evaluation value corresponding to a range of crystal convexity, an evaluation value corresponding to a range of crystal concavity, an evaluation value corresponding to a crystal quality condition, an evaluation value corresponding to a thickness of a crystal slice, and an evaluation value corresponding to a count of crystal slices.

In some embodiments, the quality parameter may further include a crystallization curve, a carbonation curve, or a combination thereof.

The crystallization curve may reflect a crystallization situation during the crystal growth process, with a horizontal axis being the time and a vertical axis being the crystallization situation (e.g., a crystallization radius, a crystallization thickness, etc.). The crystallization curve may be generated in real time based on the crystallization situation and the time during a current growth process.

The carbonation curve may reflect a carbonation situation during the crystal growth process, with a horizontal axis being the time and a vertical axis being the carbonation situation (e.g., a distance of the center of an hourglass from the bottom of the feedstock, the depth of the hourglass, etc.). This carbonization curve may be generated in real time based on the carbonization situation and the time during the current growth process. Further description of the hourglass may be found in the related description later.

Each evaluation value in the quality parameter may be represented by a value from 0-10, with larger values indicating better growth result quality for the corresponding evaluation item.

In some embodiments, the processor may perform a crystal growth process simulation based on the target control recipe to obtain a simulated growth result. The simulated growth results include growth result data generated by the system simulation. More details regarding the growth result data may be found in FIG. 4 and the related descriptions.

In some embodiments, the processor may process the simulated growth result and the target growth result based on a third preset rule to determine the quality parameter.

In some embodiments, an exemplary third preset rule may be: comparing a thickness difference between the crystal thickness in the simulated growth result and the crystal thickness in the target growth result with a plurality of preset thickness difference ranges, and determining an evaluation value corresponding to the preset thickness difference range to which the thickness difference belongs as the evaluation value corresponding to an evaluation item of the crystal thickness. A correspondence between the preset thickness difference ranges and the evaluation value may be preset by the system or by a human. The rules for determining the other evaluation values in the quality parameter are similar to the rules for determining the evaluation value corresponding to the evaluation item of the crystal thickness, and will not be repeated here.

In some embodiments, the processor may perform the crystal growth process simulation based on the target control recipe to obtain simulated response conditions in different crystal growth processes. In turn, the processor may determine the quality parameter by analyzing and processing the simulated response conditions in different crystal growth processes.

A simulated response condition refers to a response condition simulated of feedstock during the crystal growth process. For example, the feedstock may be silicon carbide powder. In some embodiments, the simulated response conditions may include a simulated crystallization condition and a simulated carbonization condition.

The simulated crystallization condition refers to a phenomenon where the feedstock crystallizes in the simulated crystal growth process. In some embodiments, the simulated crystallization condition may include a crystallization radius and a crystallization thickness of an upper portion of the feedstock in a discharge position, a crystallization radius and a crystallization thickness of a bottom portion of a crucible, a feedstock volatility, or the like.

The simulated carbonization condition refers to the phenomenon where the feedstock undergo carbonization during the simulated crystal growth process. The carbonization refers to a process that proceeds inward toward the center, resulting in the formation of an hourglass shaped carbon powder in a middle of the feedstock. In some embodiments, the simulated carbonization condition may include the distance of the center of the hourglass from the bottom of the feedstock, the depth of the hourglass (a distance from an edge of the feedstock to the center of the hourglass), or the like.

In some embodiments, the processor may analyze and process the simulated response conditions of the different growth processes in a plurality of ways to determine the quality parameter. For example, the processor may determine the quality parameter by processing, such as data fitting, the simulated response conditions in the different growth processes.

In some embodiments, the processor presents the simulation process of the crystal growth process based on the target control recipe, and the quality parameter reflecting growth result quality to a user via a user terminal. In some embodiments, the simulation process and a simulation result of the simulation process may be sent to the user in a form of a message. For example, the simulation process and the simulation result may be sent to a client of the user via a reminder message. In some embodiments, the processor may transfer the simulation process and the simulation result to the storage device for storage. The storage device may be a storage device integrated in the system for controlling the crystal growth device, or may be a storage device outside of the system, e.g., a CD, a hard disk, or the like. In some embodiments, the simulation process and the simulation result of the simulation process may be communicated to a specific interface. The interface includes, but is not limited to, a program interface, a data interface, a transmission interface, or the like. In some embodiments, the simulation process and the simulation result may also be output in any way known to the person skilled in the art, for example, by displaying in a local control terminal, which is not limited by the present disclosure.

In some embodiments of the present disclosure, by simulating the target control recipe through the system, the condition of the feedstock is predicted, providing a means to monitor the quality of crystals or the growth result.

It should be noted that the foregoing descriptions of the processes 400, 600, 700, 900, and 1000 are intended to be exemplary and illustrative only, and do not limit the scope of application of the present disclosure. For a person skilled in the art, various corrections and changes may be made to the processes 400, 600, 700, 900, and 1000 under the guidance of the present disclosure. However, the corrections and changes remain within the scope of the present disclosure.

FIG. 11 is an exemplary schematic diagram illustrating a process for determining a target control recipe of a target crystal growth device according to some embodiments of the present disclosure.

In some embodiments, the processor may determine a predicted growth result 1104 of each of at least one preset control recipe 1102 by using a recipe determination model 1103 to process a control mode 1101 of a target crystal growth device and the each of the at least one preset control recipe 1102, and determine a target control recipe 1106 based on the predicted growth result 1104 and a target growth result 1105. More details regarding the preset control recipe may be found in FIG. 10 and the related descriptions.

In some embodiments, the processor may determine the target control recipe 1106 based on the predicted growth result 1104 and the target growth result 1105 of the target crystal growth device in a plurality of ways.

In some embodiments, the processor may determine, from multiple predicted growth results, the predicted growth result that is close to the target growth result 1105, and identify a preset control recipe corresponding to the predicted growth result as the target control recipe 1106. In some embodiments, determining whether the predicted growth result and the target growth result are close may be achieved by determining a vector distance between vectors representing the predicted growth result and the target growth result in the recipe determination model, and when the vector distance between the two is less than a distance threshold, it may be determined that the predicted growth result and the target growth result are close.

The predicted growth result refers to predicted growth result data obtained by controlling the target crystal growth device according to the preset control recipe. For example, the predicted growth result may include a predicted thickness, a predicted size, a predicted range of convexity, a predicted range of concavity, a predicted crystal quality condition, a predicted thickness of a slice, a predicted count of the slices of the crystals, etc. More details regarding the growth result data may be found in FIG. 4 and the related descriptions.

The recipe determination model 1103 refers to a machine learning model for determining the target control recipe of the target crystal growth device. For example, the recipe determination model 1103 may include one of a DNN model, a CNN model, etc., or any combination thereof.

In some embodiments, the recipe determination model 1103 includes more than eight hundred multiplication operations in a single execution. In some embodiments, the recipe determination model 1103 is at least partially executed by a GPU.

In some embodiments, an input of the recipe determination model 1103 may include the control mode 1101 of the target crystal growth device and the at least one preset control recipe 1102, and an output may include the preset control recipe 1102 of the each of the at least one preset growth result 1104. More details regarding the control mode may be found in FIG. 4 and the related descriptions.

In some embodiments, the processor may determine the target control recipe 1106 by using the recipe determination model 1103 to process the control mode 1101 of the target crystal growth device, the at least one preset control recipe 1102, and the target growth result 1105. Correspondingly, the input of the recipe determination model 1103 may include the control mode 1101 of the target crystal growth device, the at least one preset control recipe 1102, and the target growth result 1105 of the target crystal growth device, and the output may include the target control recipe 1106 of the target crystal growth device.

In some embodiments, the recipe determination model 1103 may be obtained by: obtaining a plurality of third training samples 1107 and third labels 1108 corresponding to the plurality of third training samples 1107, and based on the plurality of third training samples 1107 and the third labels 1108, performing training to obtain the recipe determination model 1103.

Exemplarily, the processor may input each of the plurality of third training samples 1107 with the third labels 1108 into an initial recipe determination model 1109, construct a loss function through one of the third labels 1108 corresponding to the each of the plurality of third training samples and an output of the initial recipe determination model 1109, and iteratively update parameters of the initial recipe determination model 1108 through gradient descent or other manners based on the loss function. When a preset condition is satisfied, the training of the initial recipe determination model 1108 is completed and the trained recipe determination model 1103 is obtained. The preset condition may be that the loss function converges, a count of iterations reaches a threshold, or the like.

In some embodiments, each of the third training samples 1107 include a historical control mode and a historical control recipe for a third sample crystal growth device. In some embodiments, the third sample crystal growth devices may include a plurality of crystal growth devices. In some embodiments, the third sample crystal growth devices may include the target crystal growth device. In some embodiments, the third sample crystal growth device may be the same as at least one of the first sample crystal growth device or the second sample crystal growth device.

In some embodiments, each of the third labels 1108 may include a historical growth result corresponding to the historical control recipe.

In some embodiments, each of the third labels 1108 may also include the historical control recipe corresponding to the best historical growth result in the case of a plurality of historical control recipes.

In some embodiments, the third training samples 1107 may be determined based on historical growth data of the plurality of crystal growth devices. The third labels 1108 may be determined by human labeling.

In some embodiments of the present disclosure, the recipe determination model can determine the target control recipe for the target crystal growth device based on a large number of extensive features, which enables the predicted target control recipe to achieve higher accuracy, thereby facilitating high-precision automated control of the crystal growth process in actual production.

The basic concepts have been described above, and it is clear that to a person skilled in the art, the above-detailed disclosure serves only as an example and does not constitute a limitation of the present disclosure. While not expressly stated herein, various modifications, improvements, and amendments may be made to the present disclosure by those skilled in the art. The types of modifications, improvements, and amendments are suggested in the present disclosure, so the types of modifications, improvements, and amendments remain within the spirit and scope of the exemplary embodiments of the present disclosure.

Also, the present disclosure uses specific words to describe the exemplary embodiments of the present disclosure. Such as “an embodiment”, “one embodiment”, and/or “some embodiment” means a feature, structure, or characteristic associated with at least one embodiment of the present disclosure. Accordingly, it should be emphasized and noted that “an embodiment” or “one embodiment” referred to two or more times in different positions in the present disclosure do not necessarily refer to the same embodiment. In addition, certain features, structures, or characteristics in one or more embodiments of the present disclosure may be suitably combined.

In addition, unless expressly stated in the claims, the order of the processing elements and sequences, the use of numerical letters, or the use of other names as described in the present disclosure are not intended to qualify the order of the processes and methods of the present disclosure. While some embodiments of the invention that are currently considered useful are discussed in the foregoing disclosure by way of various examples, it is to be understood that such details serve only illustrative purposes and that additional claims are not limited to the disclosed embodiments!, rather, the claims are intended to cover all amendments and equivalent combinations that are consistent with the substance and scope of the embodiments of the present disclosure. For example, although the implementation of various components described above may be embodied in a hardware device, it may also be implemented as a software only solution, e.g., an installation on an existing server or mobile device.

Similarly, it should be noted that to simplify the presentation of the disclosure of the specification, and thereby aid in the understanding of one or more embodiments of the invention, the foregoing descriptions of embodiments of the present disclosure sometimes combine a variety of features into a single embodiment, accompanying drawings, or descriptions thereof. However, this method of disclosure does not imply that the objects of the present disclosure require more features than those mentioned in the claims. Rather, claimed subject matter may lie in less than all features of a single foregoing disclosed embodiment.

Numbers describing the number of compositions, attributes are used in some embodiments, and it should be understood that such numbers used in the description of embodiments, in some examples, be modified by terms such as “about”, “approximately”, or “generally”. Unless otherwise noted, the terms “about,” “approximate,” or “generally” indicates that a ±20% variation in the stated number is allowed. Correspondingly, in some embodiments, the numerical parameters used in the present disclosure and claims are approximations, which may change depending on the desired characteristics of individual embodiments. In some embodiments, the numerical parameters should take into account the specified number of valid digits and employ general place-keeping. While the numerical domains and parameters used to confirm the breadth of the ranges in some embodiments of the present disclosure are approximations, in specific embodiments such values are set to be as precise as possible within the range of feasibility.

For each of the patents, patent applications, patent application disclosures, and other materials cited in the present disclosure, such as articles, books, specification sheets, publications, documents, or the like, the entire contents thereof are hereby incorporated herein by reference. Application history documents that are inconsistent with or conflict with the contents of the present disclosure are excluded, as are documents (currently or hereafter appended to the present disclosure) that limit the broadest scope of the claims of the present disclosure. It should be noted that to the extent that there is an inconsistency or conflict between the descriptions, definitions, and/or use of terms in the materials appurtenant to the present disclosure and those set forth herein, the descriptions, definitions and/or use of terms in the present disclosure shall control. use shall prevail.

Finally, it should be understood that the embodiments described in the present disclosure are used only to illustrate the principles of the embodiments of the present disclosure. Other deformations may also fall within the scope of the present disclosure. As such, alternative configurations of embodiments of the present disclosure may be viewed as consistent with the teachings of the present disclosure as an example, not as a limitation. Correspondingly, the embodiments of the present disclosure are not limited to the embodiments expressly presented and described herein.

1. A method for controlling a crystal growth device, comprising:
obtaining historical growth data of at least one crystal growth device, wherein the historical growth data includes historical growth control data and historical growth result data; and
determining a control mode of a target crystal growth device based on the historical growth data and a target growth result, wherein the control mode includes at least one of a temperature control mode or a power control mode.

2. The method of claim 1, wherein the historical growth data further includes one or more historical device parameters of each of the at least one crystal growth device, and the determining a control mode of a target crystal growth device based on the historical growth data and a target growth result, includes:
obtaining one or more device parameters of the target crystal growth device; and
determining the control mode of the target crystal growth device based on the one or more device parameters, the historical growth data, and the target growth result.

3. The method of claim 2, wherein the determining the control mode of the target crystal growth device based on the one or more device parameters, the historical growth data, and the target growth result includes:
determining the control mode of the target crystal growth device by using a control recommendation model to process the one or more device parameters and the target growth result, the control recommendation model being a machine learning model, and training samples of the control recommendation model including the historical growth data.

4. The method of claim 3, wherein the control recommendation model is obtained by:
obtaining a plurality of first training samples and first labels corresponding to the plurality of first training samples, each of the first training samples including a historical device parameter and a historical growth result of a first sample crystal growth device, a first label of the first training sample including a historical control mode and/or a historical growth control parameter of the first sample crystal growth device; and
obtaining the control recommendation model by performing training based on the first training samples and the first labels.

5. The method of claim 1, further comprising:
determining one or more growth control parameters of the target crystal growth device based on the control mode and the target growth result.

6. The method of claim 1, wherein the determining a control mode of a target crystal growth device includes:
determining a first control mode when the target crystal growth device is in a first control stage, the first control stage being a feedstock preheating stage.

7. The method of claim 6, further comprising:
in response to the first control mode being the power control mode, determining a first target power for the first control stage, the first target power being configured to control the target crystal growth device during the first control stage;
determining a first target pressure for the first control stage based on the first target power.

8. (canceled)

9. The method of claim 1, wherein the determining a control mode of a target crystal growth device includes:
determining a second control mode when the target crystal growth device is in a second control stage, the second control stage being a crystal growth stage.

10. The method of claim 9, further comprising:
in response to the second control mode being the temperature control mode, determining a target temperature for the second control stage;
obtaining a current growth temperature of the target crystal growth device; and
determining a target growth power of the target crystal growth device based on the current growth temperature and the target temperature, the target growth power being configured to control the target crystal growth device in the second control stage; wherein the obtaining a current growth temperature of the target crystal growth device includes:
obtaining the current growth temperature based on at least three temperature measurement points, the at least three temperature measurement points having different axial positions.

11. (canceled)

12. The method of claim 10, wherein the determining a target growth power of the target crystal growth device based on the current growth temperature and the target temperature includes:
determining the target growth power of the target crystal growth device by using a power determination model to process the current growth temperature and the target temperature; wherein the power determination model is obtained by:
obtaining a plurality of second training samples and second labels corresponding to the plurality of second training samples, each of the second training samples including a historical current growth temperature and a historical target temperature of a second sample crystal growth device when the second control mode is the temperature control mode, the second label of the second training sample including a historical target growth power; and
obtaining the power determination model by performing training based on the plurality of second training samples and the second labels.

13. (canceled)

14. The method of claim 9, further comprising:
in response to the second control mode being the power control mode, determining a second target power for the second control stage, the second target power being configured to control the target crystal growth device in the second control stage.

15. The method of claim 14, further comprising:
obtaining a current growth temperature of the target crystal growth device;
in response to a fluctuation of the current growth temperature being greater than a preset fluctuation threshold, switching the second control mode from the power control mode to the temperature control mode.

16. The method of claim 9, further comprising:
determining a target temperature field distribution for the second control stage based on the second control mode; and
determining one or more thermal insulation parameters of the target crystal growth device based on the target temperature field distribution; wherein the insulation parameter includes at least one of an outer diameter parameter of a first insulation layer, an inner diameter parameter of the first insulation layer, a first thickness parameter of the first insulation layer, and a second thickness parameter of a second insulation layer; and
determining one or more recommendation schemes of thermal insulation layers based on the one or more thermal insulation parameters.

17-19. (canceled)

20. The method of claim 1, further comprising:
determining a target control recipe of the target crystal growth device based on the control mode.

21. The method of claim 20, wherein the determining a target control recipe of the target crystal growth device based on the control mode includes:
determining a predicted growth result of each of at least one preset control recipe by using a recipe determination model to process the control mode and the each of the at least one preset control recipe; and
determining the target control recipe based on the predicted growth result of each of at least one preset control recipe and the target growth result.

22. The method of claim 21, wherein the recipe determination model is obtained by:
obtaining a plurality of third training samples and third labels corresponding to the plurality of third training samples, each of the third training samples including a historical control mode and a historical control recipe of a third sample crystal growth device, and the third label of the third training sample including a historical growth result corresponding to the historical control recipe;
obtaining the recipe determination model by performing training based on the plurality of third training samples and the third labels.

23. The method of claim 20, wherein the determining a target control recipe of the target crystal growth device based on the control mode includes:
determining the target control recipe by using a recipe determination model to process the control mode, at least one preset control recipe, and the target growth result.

24. The method of claim 20, further comprising:
performing a crystal growth process simulation based on the target control recipe to determine a quality parameter reflecting growth result quality; wherein the quality parameter includes at least one of a crystallization curve or a carbonation curve.

25. (canceled)

26. A system for controlling a crystal growth device, comprising:
an obtaining module for obtaining historical growth data of at least one crystal growth device, wherein the historical growth data includes historical growth control data and historical growth result data; and
a determination module for determining a control mode of a target crystal growth device based on the historical growth data and a target growth result, wherein the control mode includes at least one of a temperature control mode or a power control mode.

27. A device for controlling a crystal growth device, comprising a processor, wherein the processor is used to perform the method for controlling the crystal growth device, including:
obtaining historical growth data of at least one crystal growth device, wherein the historical growth data includes historical growth control data and historical growth result data; and
determining a control mode of a target crystal growth device based on the historical growth data and a target growth result, wherein the control mode includes at least one of a temperature control mode or a power control mode.
